(19) United States
(12) Patent Application Publication
(10) Pub. No.: US 2014/0174907 A1
(43) Pub. Date: Jun. 26, 2014

(54) High Deposition Rate Chamber with Co-Sputtering Capabilities

(71) Applicant: INTERMOLECULAR, INC., San Jose, CA (US)

(72) Inventors: Hong Sheng Yang, Pleasanton, CA (US); Kent Riley Child, Dublin, CA (US); Chi-I Lang, Cupertino, CA (US); James Tsung, Milpitas, CA (US)

(73) Assignee: INTERMOLECULAR, INC., San Jose, CA (US)

(21) Appl. No.: 13/725,133

(22) Filed: Dec. 21, 2012

(51) Int. Cl. C23C 14/34

(52) U.S. Cl. CPC C23C 14/34
USPC 204/192.1; 204/298.15

(57) ABSTRACT

A deposition chamber is provided. The deposition chamber includes a plurality of sputter guns disposed within the chamber, wherein the plurality of sputter guns are operable to vertically extend and retract within the chamber and wherein each gun of the plurality of sputter guns is pivotable around a pivot axis. The chamber includes a substrate support rotatable around a first axis and a second axis and a plate disposed over the substrate support. The plate has a plurality of apertures extending therethrough. The plurality of apertures includes an aperture located below each sputter gun of the plurality of sputter guns and a centrally located aperture.

### BACKGROUND

Physical vapor deposition (PVD) is commonly used within the semiconductor industry as well as solar, glass coating, and other industries, in order to deposit a layer over a substrate. Sputtering is a common physical vapor deposition method where atoms or molecules are ejected from a target material by high-energy particle bombardment and then deposited onto the substrate.

In order to identify different materials, evaluate different unit process conditions or parameters, or evaluate different sequencing and integration of processes, and combinations thereof, it may be desirable to be able to process different regions of the substrate differently. This capability, hereinafter called “combinatorial processing”, is generally not available with tools that are designed specifically for conventional full substrate processing. Furthermore, it may be desirable to subject localized regions of the substrate to different processing conditions (e.g., localized deposition) in one step of a sequence followed by subjecting the full substrate to a similar processing condition (e.g., full substrate deposition) in another step.

Current full-substrate PVD tools used in the semiconductor industry have a large sputtering source including a large sputtering target, i.e., the target is larger than the substrate in order to deposit a uniform layer on the substrate, even for substrates as large as 300 mm wafer. Alternatively, some full substrate PVD tools use a smaller sputtering source, e.g., 3″ or 4″ diameter target, and rotate the wafer in order to deposit a uniform film, where the substrate may be 200 mm diameter or smaller and the sputtering source is pointed to approximately the mid-radius of the substrate. In these methods, the target-to-substrate spacing is relatively large, e.g., 200 mm, requiring significant space between the sputtering source and the substrate in order to deposit a uniform film on the full substrate.

Combinatorial processing chambers typically include smaller sputtering sources. However, deposition rates can suffer. A plurality of small sputtering sources aimed at a common location on a substrate must be positioned at a significant distance from the substrate to ensure good uniformity of the deposited film within an isolated spot. Particularly for thick film applications such as the formation of metal and metal nitride electrodes, process times of several hours are common. Significant contamination and poor film quality are common byproducts of long processing time.

### SUMMARY

In some embodiments, a deposition chamber is provided. The deposition chamber includes a plurality of sputter guns disposed within the chamber, wherein the plurality of sputter guns are operable to vertically extend and retract through a lid of the chamber and wherein each gun of the plurality of sputter guns is pivotable. The chamber includes a substrate support rotatable around a first axis and a second axis and a plate disposed over the substrate support. The plate has a plurality of apertures extending therethrough. The plurality of apertures includes an aperture located below each sputter gun of the plurality of sputter guns and a centrally located aperture.

In some embodiments, a method for combinatorially processing a substrate is provided. The method includes receiving a substrate into a processing chamber and exposing a plurality of regions of the substrate. The method includes depositing different materials in each region of the plurality of regions through a vacuum deposition process. The method includes rotating the substrate and pivoting each sputter gun of a plurality of sputter guns sputter gun without breaking vacuum in the processing chamber. The method includes depositing material from each sputter gun of a plurality of sputter guns sputter gun onto one region of the plurality of regions.

### BRIEF DESCRIPTION OF DRAWINGS

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system in accordance with some embodiments of the invention.

FIG. 4 is a simplified schematic diagram illustrating a sputter chamber configured to perform combinatorial processing and full substrate processing in accordance with some embodiments of the invention.

FIG. 5 is a schematic diagram illustrating a sputter gun having in-situ pivoting capabilities in accordance with some embodiments of the invention.

FIG. 6 illustrates an exemplary embodiment of an aperture plate which may be utilized in accordance with some embodiments.

FIG. 7 is a flowchart of the method operations for combinatorially processing a substrate in some embodiments.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

The embodiments provide for a deposition chamber that is capable of providing a relatively high deposition rate as the sputter guns can be placed in close proximity to the surface of the substrate. The sputter guns can also be pivoted in-situ to allow, without breaking vacuum in the chamber, for co-sputtering for combinatorial processing. The in-situ pivoting enables switching from a high deposition close range sputtering to a co-sputtering configuration in an efficient manner. The chamber utilizes a multi-aperture plate that has an aperture dedicated for each sputter gun when utilized in a high deposition rate mode, i.e., close to the surface of the substrate, and a shared aperture when the guns are utilized in a co-sputtering mode, i.e., the guns are moved away from the substrate surface and the target surfaces are pivoted toward the shared aperture. In the high deposition rate mode embodiments, the target to substrate spacing is about 20-100 mm. In the co-sputtering deposition embodiments, the target to substrate spacing is about 100-400 mm. Each of the sputter guns includes a bottom shield that is rotatable to expose or conceal the target surface. The substrate support is rotatable around at least two axes in order to access any region of the substrate through the shared aperture or other apertures of the multi-aperture plate.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

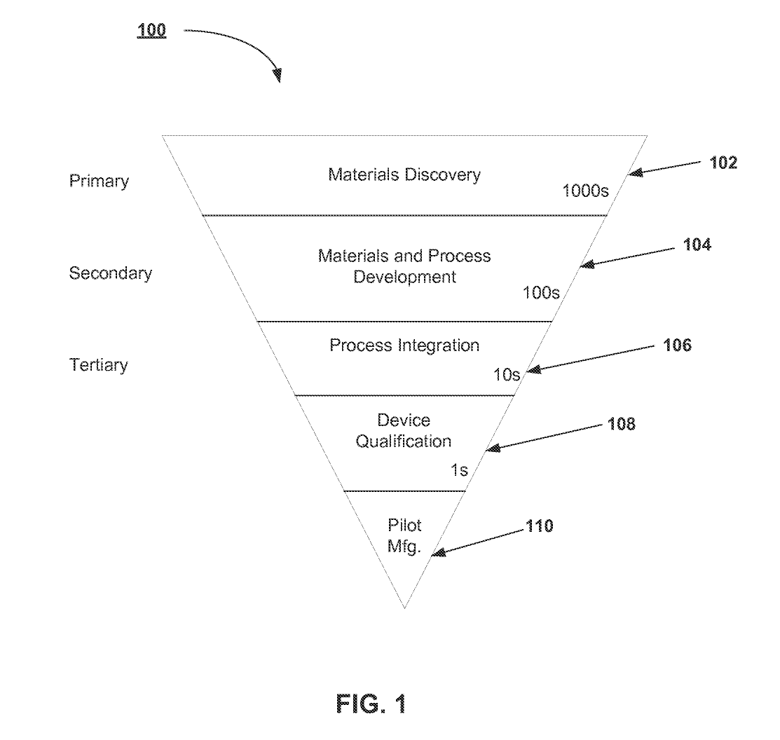

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

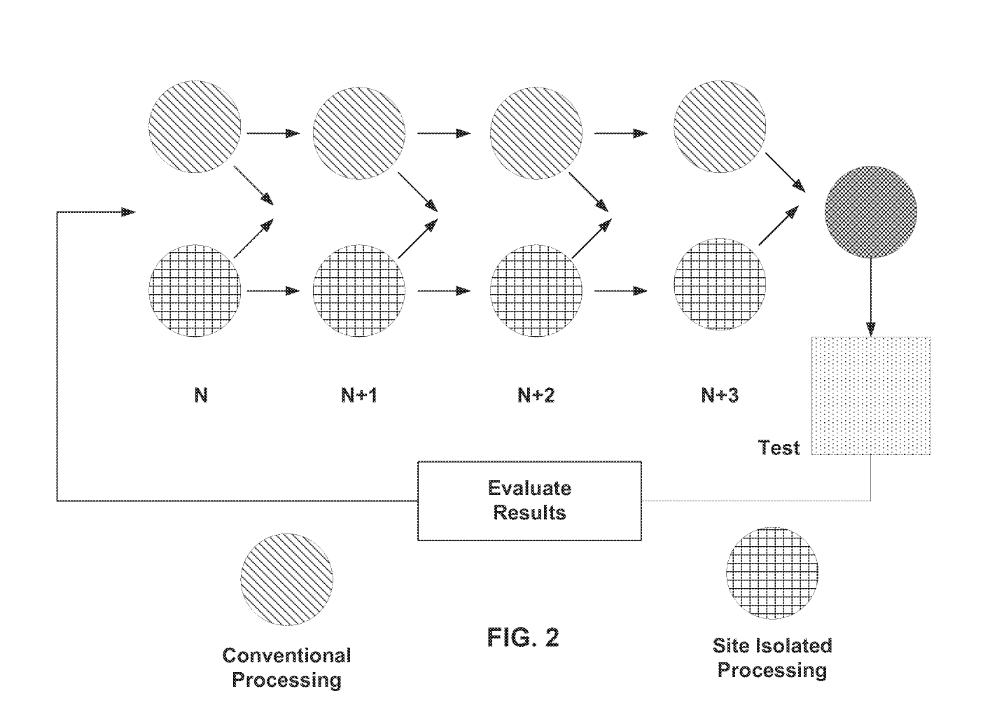

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

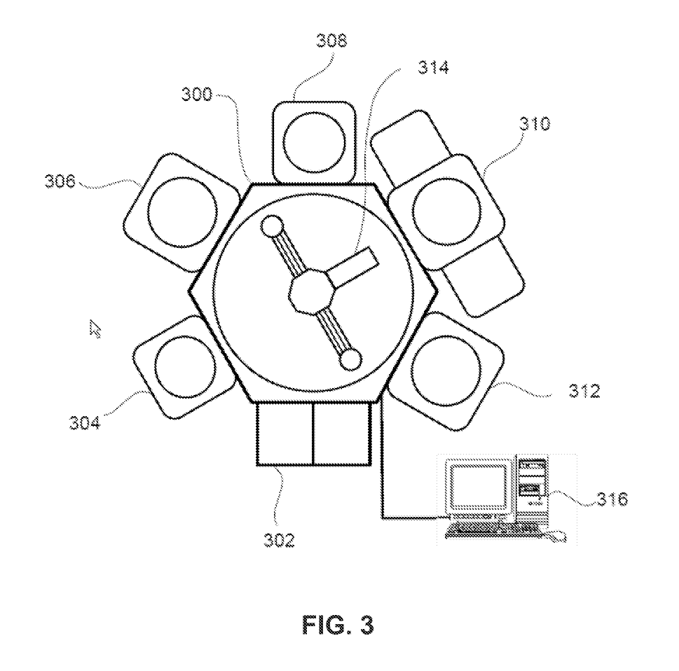

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

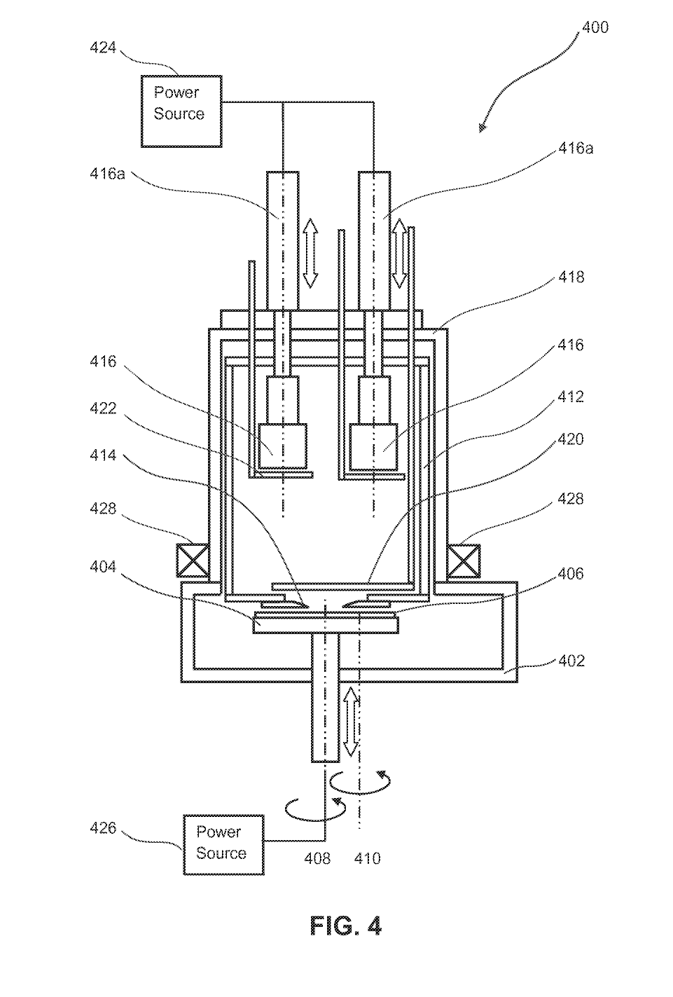

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424. Further details of the power sources and their operation may be found in U.S. patent application Ser. No. 13/281,316 entitled “High Metal Ionization Sputter Gun” filed on Oct. 25, 2011 and is herein incorporated by reference.

Substrate 406 may be a conventional round 200 mm, 300 mm, or any other larger or smaller substrate/wafer size. In other embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun pivot angle and target-to-substrate spacing, and by using multiple sputter guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two sputters 416 are illustrated in FIG. 4. Sputter guns 416 are moveable in a vertical direction so that one or both of the guns may be lifted from the slots of the shield. While two sputter guns (also referred to as process guns) are illustrated, any number of sputter guns may be included, e.g., one, three, four or more sputter guns may be included. Where more than one sputter gun is included, the plurality of sputter guns may be referred to as a cluster of sputter guns. Gun shutter 422 can be transitioned to isolate the lifted sputter guns from the processing area defined within process kit shield 412. In this manner, the sputter guns are isolated from certain processes when desired. It should be appreciated that slide cover plate 422 may be integrated with the top of the process kit shield 412 to cover the opening as the sputter gun is lifted or individual cover plate 422 can be used for each target. In some embodiments, sputter guns 416 are oriented or angled so that a normal reference line extending from a planar surface of the target of the sputter gun is directed toward an outer periphery of the substrate in order to achieve good uniformity for full substrate deposition film. The target/gun pivot angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to sputter guns 416 may be attached to a suitable drive, e.g., lead screw, worm gear, etc., configured to vertically move sputter guns 416 toward or away from a top plate of top chamber portion 418. Arm extensions 416a may be affixed to sputter guns 416 at a pivot point to enable the sputter guns to pivot around a pivot axis relative to a vertical axis. In some embodiments, sputter guns 416 pivot toward aperture 414 when performing combinatorial processing and pivot toward a periphery of the substrate being processed when performing full substrate processing. It should be appreciated that sputter guns 416 may pivot away from aperture 414 when performing combinatorial processing in another embodiment. In yet another embodiment, arm extensions 416a are attached to a bellows that allows for the vertical movement and pivoting of sputter guns 416. Arm extensions 416a enable movement with four degrees of freedom in some embodiments. Where process kit shield 412 is utilized, the aperture openings are configured to accommodate the pivoting of the sputter guns. The amount of pivoting of the sputter guns may be dependent on the process being performed in some embodiments.

Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply.

Chamber 400 includes auxiliary magnet 428 disposed around an external periphery of the chamber. The auxiliary magnet 428 is located in a region defined between the bottom surface of sputter guns 416 and a top surface of substrate 406. Magnet 428 may be either a permanent magnet or an electromagnet. It should be appreciated that magnet 428 is utilized to provide more uniform bombardment of Argon ions and electrons to the substrate in some embodiments.

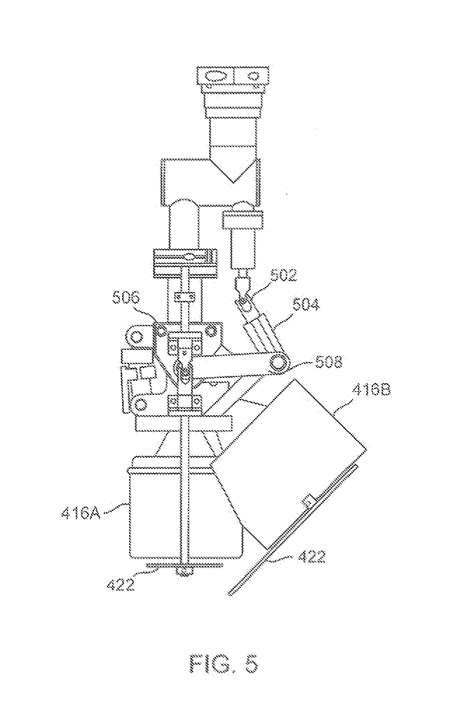

FIG. 5 is a schematic diagram illustrating a sputter gun having in-situ pivoting capabilities in accordance with some embodiments. Sputter gun 416 is operable to be pivoted through a pivoting mechanism capable of operating in-situ without breaking vacuum within the chamber housing where sputter gun 416 is disposed. A motor contained within housing 506 is configured to drive pivot bar 508 in order to change the orientation of a target disposed on a bottom surface of sputter gun 416 between the two positions 416A and 416B of sputter gun 416 illustrated in FIG. 5. The motor within housing 506 is coupled to pivot bar 508, which in turn is coupled to lead screw 504. That is, the bottom surface of sputter gun 416 pivots around a pivot axis coupled to an arm extension supporting the sputter gun. As noted above, the arm extension supports the sputter gun Lead screw 504 is coupled to U-joint 502. It should be appreciated that the motor is capable of functioning under high temperature and high vacuum processing conditions, and may be a magnetic drive, linear drive, worm screw, lead screw, a differentially pumped rotary feed through drive, etc., in some embodiments. Sputter gun 416 may be supported within the chamber in a known manner. Pivot angles and position of sputter gun 416 are controlled through a controller, such as controller 316 of FIG. 3. In some embodiments sputter gun 416 may be pivoted from 0 degrees to about 60 degrees relative to a normal axis of the target of sputter gun 416.

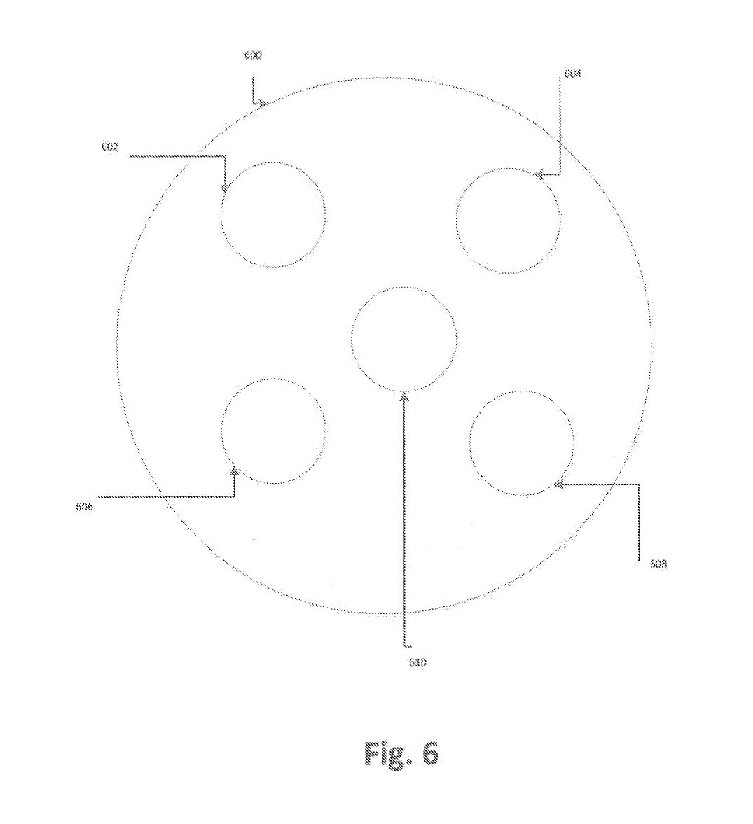

FIG. 6 illustrates an exemplary embodiment of an aperture plate which may be utilized in accordance with some embodiments. Aperture plate 600 includes apertures 602, 604, 606, 608, and 610. It should be appreciated that in an embodiment with four sputter guns, each sputter gun will be associated with one aperture when the sputter gun is in a non-pivoted mode, e.g., a high deposition rate mode where different regions are combinatorially processed. During a co-sputtering operation the sputter guns are pivoted toward aperture 610, which may be referred to as a centrally located aperture. Thus, apertures 602, 604, 606, and 608 are utilized for high deposition rate processes where the sputter gun associated with each of these apertures is relatively close to the surface of aperture plate 600. The sputter guns can then be moved away or retracted from a surface of aperture plate 600 and pivoted through the mechanism described above in order to perform a co-sputtering operation where aperture 610 is open and apertures 602, 604, 606, in 608 are closed. In some embodiments, each sputter gun, or an axis of each sputter gun, is equidistant from an axis of aperture 610. In some embodiments aperture plate 600 is integrated into the removeable insert of the process kit shield described above with reference to FIG. 4. As noted above, in the high deposition rate mode, the target to substrate spacing is about 20-100 mm in some embodiments and in the co-sputtering deposition mode, the target to substrate spacing is about 100-400 mm in some embodiments. It should be appreciated that the apertures may be blocked through moveable plates associated with each aperture or other known means. In some embodiments, the moveable plates are each independently closeable and openable. It should be appreciated that the multiple sputter guns can include targets that are different from each other, the same, or some combination of the two. It should be further appreciated that the ability to vary the targets, distances from the substrate surface, angles of the sputter guns, etc., enables numerous combinations for the combinatorial experiments and workflows described herein. In addition, combinatorial experiments can be performed in a more efficient manner due to the in situ pivoting capability of the sputter guns described herein.

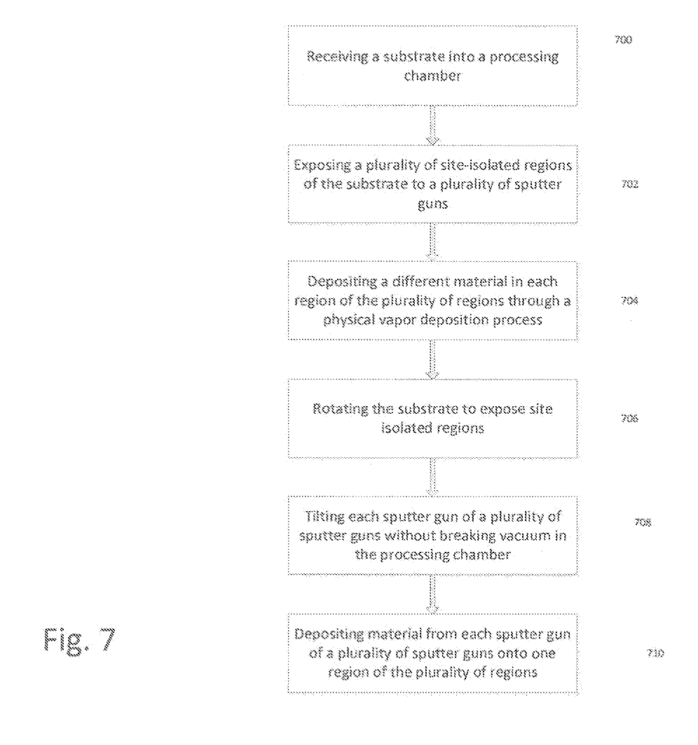

FIG. 7 is a flowchart of the method operations for combinatorially processing a substrate in some embodiments. The method initiates with receiving a substrate into a processing chamber in operation 700. The method includes exposing a plurality of site-isolated regions of the substrate to a plurality of sputter guns in operation 702. The method includes depositing a different material in each region of the plurality of regions through a physical vapor deposition process in operation 704 and rotating the substrate to expose site isolated regions in operation 706. It should be appreciated that the material for each target of the plurality of sputter guns may be composed of different materials in some embodiments. The method includes pivoting each sputter gun of a plurality of sputter guns without breaking vacuum in the processing chamber in operation 708 and depositing material from each sputter gun of a plurality of sputter guns onto one region of the plurality of regions in operation 710, the one region may be a centrally located region in some embodiments.

In the drawings, like reference numerals appearing in different drawings represent similar or same components and perform similar or same functions, unless specifically noted otherwise in the description. Furthermore, as would be appreciated by those skilled in the art, according to common practice, the various features of the drawings discussed herein are not necessarily drawn to scale, and that dimensions of various features, structures, or characteristics of the drawings may be expanded or reduced to more clearly illustrate various implementations of the invention described herein.

Implementations of the invention may be described as including a particular feature, structure, or characteristic, but every aspect or implementation may not necessarily include the particular feature, structure, or characteristic. Further, when a particular feature, structure, or characteristic is described in connection with an aspect or implementation, it will be understood that such feature, structure, or characteristic may be included in connection with other implementations, whether or not explicitly described. Thus, various changes and modifications may be made to the provided description without departing from the scope or spirit of the invention. As such, the specification and drawings should be regarded as exemplary only, and the scope of the invention to be determined solely by the appended claims.

What is claimed is:

1. A deposition chamber, comprising:
a plurality of sputter guns disposed within the chamber,
a plurality of arm extensions, wherein each of the plurality of arm extensions has a pivot point;
wherein each sputter gun of the plurality of sputter guns is respectively affixed to an arm extension of the plurality of arm extensions at the pivot point of the arm extension,
wherein each sputter gun is operable to independently vertically extend and retract through a lid of the chamber using the arm extension,
wherein each sputter gun of the plurality of sputter guns is pivotable around the pivot point;
a substrate support rotatable around a first axis and a second axis,
wherein the first axis and the second axis are parallel to one another, and
wherein first axis and the second axis are perpendicular to a plane of the substrate;
a plate disposed over the substrate support, the plate having a plurality of apertures extending therethrough,
wherein the plurality of apertures includes an aperture located below each sputter gun of the plurality of sputter guns, and an aperture located at a center of the plate,
wherein the aperture located below each sputter gun shares an axis with the respective sputter gun.

2. The chamber of claim 1, wherein pivoting of each of the sputter guns is achieved without breaking vacuum within the chamber.

3. The chamber of claim 1, wherein different site-isolated regions of a substrate supported on the substrate support are processed in a combinatorial manner.

4. The chamber of claim 1, wherein each sputter gun of the plurality of sputter guns is equidistant from an axis of the aperture located at the center of the plate.

5. The chamber of claim 1, wherein each aperture of the plurality of apertures is independently closeable.

6. The chamber of claim 1, wherein a target of each sputter gun is composed of a different material.

7. The chamber of claim 1, wherein a diameter of a target of each gun of the plurality of sputter guns is less than a diameter of the substrate.

8. The chamber of claim 1, wherein each gun of the plurality of sputter guns includes a motor operable to adjust an angle of orientation of a target surface for each gun relative to a surface of the substrate support.

9. The chamber of claim 1, wherein a diameter of each aperture of the plurality of apertures is equal.

10. The chamber of claim 1, wherein the plate remains stationary as the substrate support rotates.

11. The chamber of claim 1, wherein during a co-sputtering operation where multiple sputter guns are contemporaneously providing material for a sputtering operation, each of the multiple sputter guns are pivoted toward the aperture located at the center of the plate.

12. The chamber of claim 11, wherein each sputter gun provides a different material composition toward the aperture located at the center of the plate.

13. The chamber of claim 1, wherein the plate is integrated into a removable insert for the chamber.

14. A method of combinatorially processing a substrate, comprising:
receiving a substrate into a processing chamber;
exposing a plurality of site-isolated regions of the substrate to a plurality of sputter guns;
depositing a different material in each region of the plurality of regions through a physical vapor deposition process;
rotating the substrate;
pivoting each sputter gun of a plurality of sputter guns without breaking vacuum in the processing chamber; and
depositing material from each sputter gun of a plurality of sputter guns onto one region of the plurality of regions.

15. The method of claim 14, wherein depositing the material from each sputter gun includes pivoting each sputter gun toward the one region of the plurality of regions.

16. The method of claim 14, wherein depositing the material from each sputter gun includes closing apertures exposing each of the plurality regions except the one region.

17. The method of claim 14, wherein the pivoting includes increasing a distance between each sputter gun and a surface of the substrate.

18. The method of claim 14, wherein rotating the substrate includes selecting one of a first axis or a second axis to rotate the substrate around.
